(19) United States
(12) Patent Application Publication
(10) Pub. No.: US 2017/0049004 A1
(43) Pub. Date: Feb. 16, 2017

(54) Heat Dissipation Device With Charging Function

(71) Applicant: Yu-Wen Tsai, New Taipei City (TW)

(72) Inventor: Yu-Wen Tsai, New Taipei City (TW)

(21) Appl. No.: 14/821,801

(22) Filed: Aug. 10, 2015

(51) Int. Cl. H05K 7/20; H02J 7/00

(52) U.S. Cl. CPC H05K 7/2039; H02J 7/0042; H02J 7/0052; H02J 2007/0062

(57) ABSTRACT

Disclosed is a heat dissipation device with a charging function, which includes a housing, which includes at least one heat dissipation element arranged therein. The housing has one end to which at least one elastic element and at least one first connector are mounted in such a way that a guiding opening is arranged between the elastic element and the first connector. The housing has an opposite end to which at least one second connector is mounted. The housing includes at least one air outlet opening formed in a predetermined location thereof. The housing has a surface on which a switch is mounted. The first connector, the second connector, and the heat dissipation element are in electrical connection with each other. The heat dissipation element is electrically connected to the switch. With such an arrangement, an effect of charging and dissipation heat at the same time can be achieved.

### (a) TECHNICAL FIELD OF THE INVENTION

The present invention relates generally to a heat dissipation device with a charging function, which is generally made up of a heat dissipation element, a first connector, and a second connector, in which electrical charging is achieved with the first connector connected to an external device and the second connector connected to an electricity accumulator and heat is dissipated through a heat dissipation element to achieve both functions of electrical charging and heat dissipation.

### (b) DESCRIPTION OF THE PRIOR ART

The innovation of science and technology creates a modern living way that each person owns and operates a mobile phone and/or a tablet computer. The progress of science and technology allows a mobile phone to not only provide function of conversation but also additional functions of shopping, ticket ordering, movie watching, and photograph viewing, which can all be done with a mobile phone or a tablet computer. There are a variety of services and operations can be done with such devices, making modern people relying heavily on such devices for their modern living.

However, with the popularization and prevailing of the mobile phones and tablet computers, users have behaviors of long-term use of such mobile devices. In addition, various games and application programs are available and they are generally programs that consume a great amount of electrical power and may make central processing units of the mobile devices over-heated. In order to maintain using and operating the mobile phones or tablet computers, users may continuously operate the mobile phones or tablet computers while they are being charged. This may further increase the temperature of the mobile phones or tablet computers and is considers dangerous.

The present invention aims to allow heat to be dissipated from a mobile phone or a tablet computer when the mobile phone or tablet computer is kept in operation while being charged in order to protect the mobile phone or tablet computer and the safety of the user to eventually avoid the shortcomings of the prior art and also improve the performance thereof

### SUMMARY OF THE INVENTION

Thus, the primary object of the present invention is to provide a heat dissipation device with a charging function, in which a heat dissipation element, a first connector, and a second connector are arranged to effectively improve a charging device to provide not only a function of electrical charging, but also an effect of heat dissipation by extracting heat from the interior of a mobile phone or a tablet computer.

To achieve the above object, the present invention comprises a housing. The housing comprises at least one heat dissipation element arranged therein. The housing has an end to which at least one elastic element and at least one first connector are mounted. A guiding opening is arranged between the elastic element and the first connector. The housing has an opposite end to which at least one second connector is mounted. The housing comprises at least one air outlet opening formed in a predetermined location thereof. The housing has a surface on which a switch is mounted. The first connector, the second connector, and the heat dissipation element are in electrical connection with each other. The heat dissipation element is electrically connected to the switch.

For the elastic element mentioned above, the elastic element may comprise rubber and/or sponge.

For the air outlet opening mentioned above, the air outlet opening is formed in one lateral side of the housing.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view of the present invention.

FIG. 2 is a perspective view, partly seen through, of the present invention.

FIG. 3 is an exploded view of the present invention.

FIG. 4 is a schematic view illustrating a use of the present invention.

FIG. 5 is another schematic view illustrating the use of the present invention.

FIG. 6 is a perspective view illustrating an embodiment of a connection receptacle of the present invention.

FIG. 7 is a schematic view illustrating a use of the connection receptacle of the present invention.

FIG. 8 is a perspective view showing an embodiment of a heat dissipation element of the present invention.

FIG. 9 is a perspective view illustrating an embodiment of the present invention.

FIG. 10 is a perspective view illustrating an embodiment of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

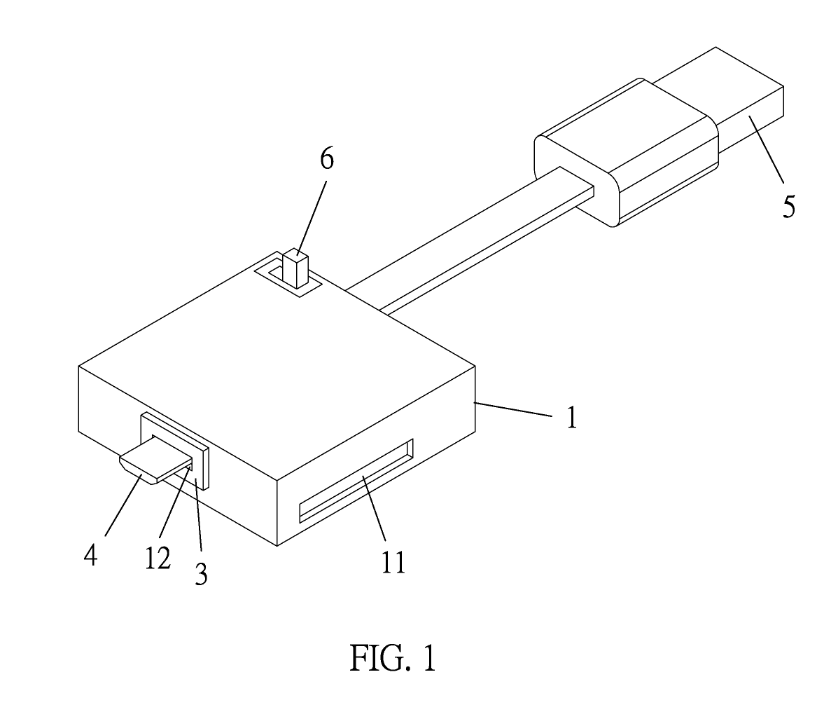

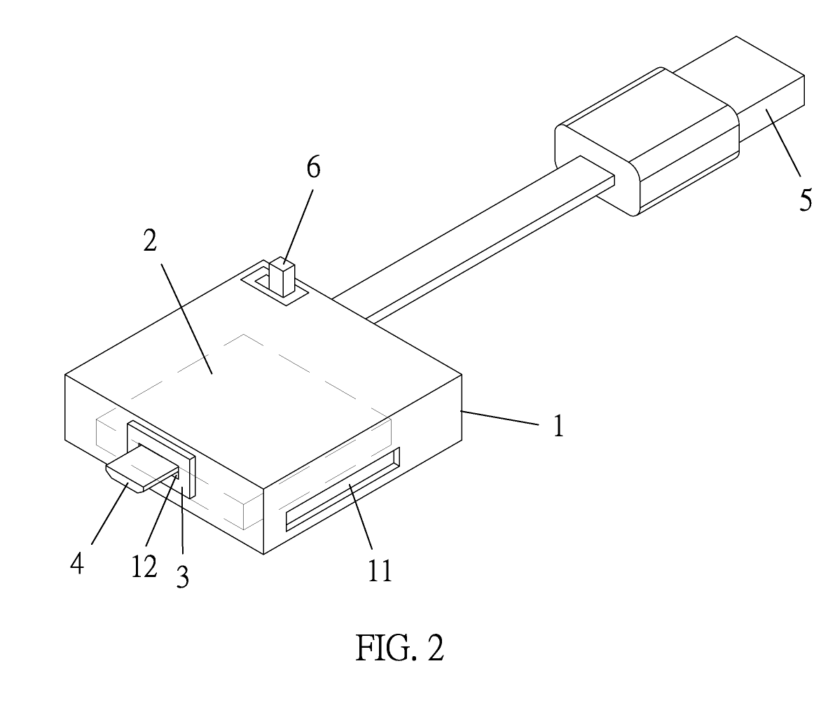

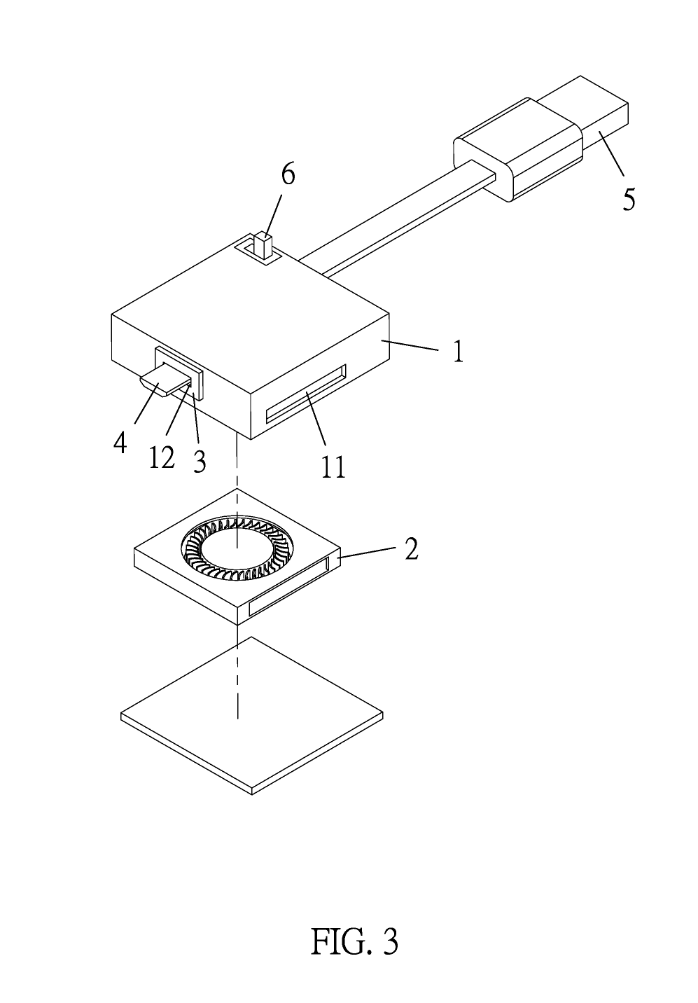

Referring to FIGS. 1-3, which are respectively a perspective view of the present invention, a perspective view, partly seen through, of the present invention, and an exploded view of the present invention, as shown in the drawings, the present invention generally comprises a housing 1. The housing 1 comprises at least one heat dissipation element 2 arranged therein. The housing 1 has an end to which at least one elastic element 3 and at least one first connector 4 are mounted. A guiding opening 12 is formed in the housing and arranged between the elastic element 3 and the first connector 4. The housing 1 has an opposite end to which at least one second connector 5 is mounted. The housing 1 has a lateral side in which at least one air outlet opening 11 is formed. The housing 1 has a major surface on which a switch 6 is mounted. The first connector 4, the second connector 5, and the heat dissipation element 2 are in electrical connection with each other. The heat dissipation element 2 is electrically connected to the switch 6.

For the elastic element 3 discussed above, the elastic element 3 may comprise rubber and/or sponge.

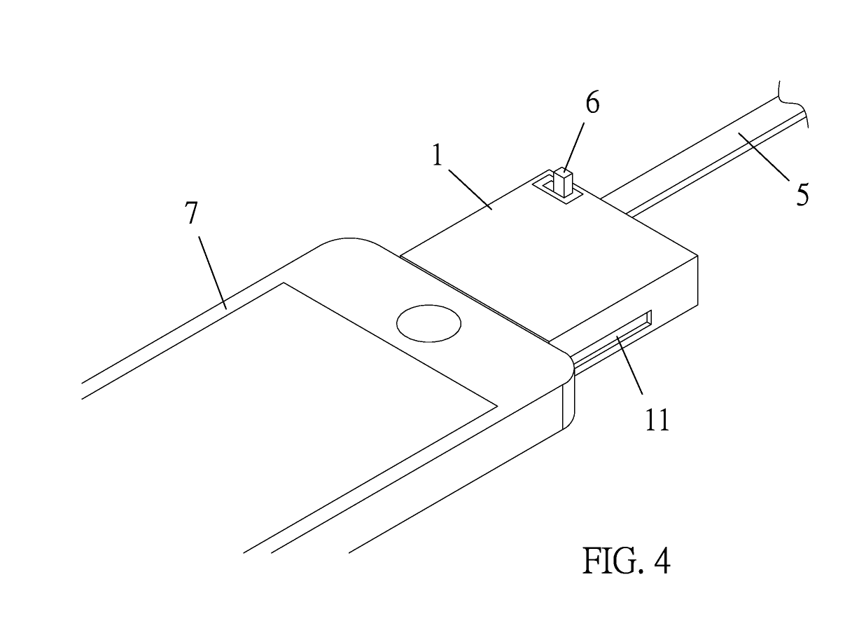

Referring to FIG. 4, which is a schematic view illustrating a use of the present invention, as shown in the drawing, the first connector 4 is connectable to a corresponding opening or channel of an external device 7 in such a way that the elastic element 3 tightly seals the connection between the first connector and the device 7. The second connector 5 is connectable to an electricity accumulator to allow the electricity accumulator to transmit electrical power to the device 7. The switch 6 is operable to activate/de-activate the heat dissipation element 2 in order to prevent over-heating when the device 7 is being charged thereby eliminating the risk of burn-out or deformation of the device 7.

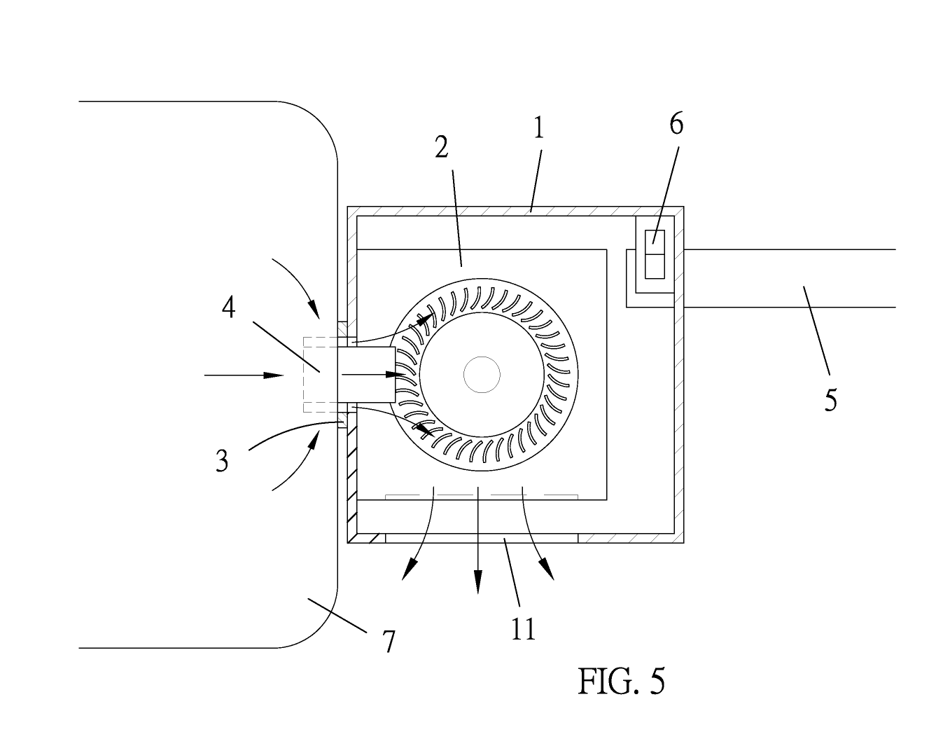

Referring to FIG. 5, which is a schematic view illustrating the use of the present invention, as shown in the drawing, connection is established between an opening or a channel of the device 7 and the first connector 4 with the elastic element 3 tightly sealing the connection between the first connector 4 and the device 7. The guiding opening 12 arranged between the elastic element 3 and the first connector 4 helps guide heat from the interior of the device 7 into the housing 1 to be subsequently conducted by the heat dissipation element 2 to the air outlet opening 11 for outward dissipation of the heat thereby achieving an effect of dissipating heat out. Oppositely, the heat dissipation element 2 may draw external air, in an opposite direction, through the air outlet opening 11 into the housing 1 and thus guided from the housing 1 through the guiding opening 12 into the interior of the device 7 to cool down the device 7, thereby achieving a similar effect.

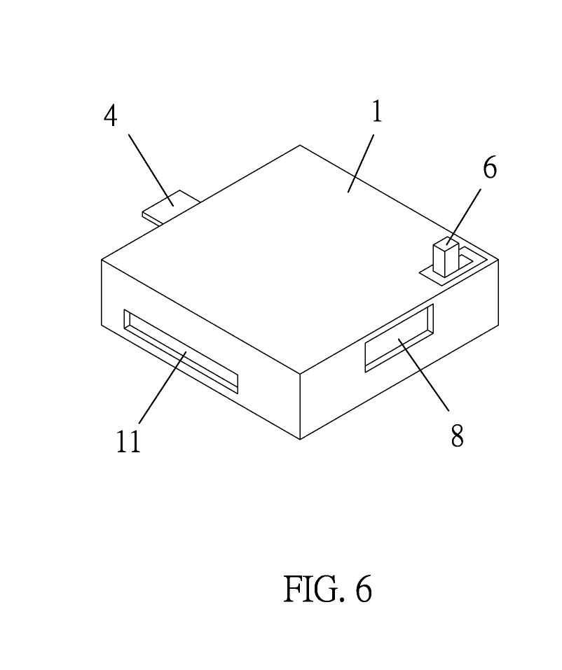

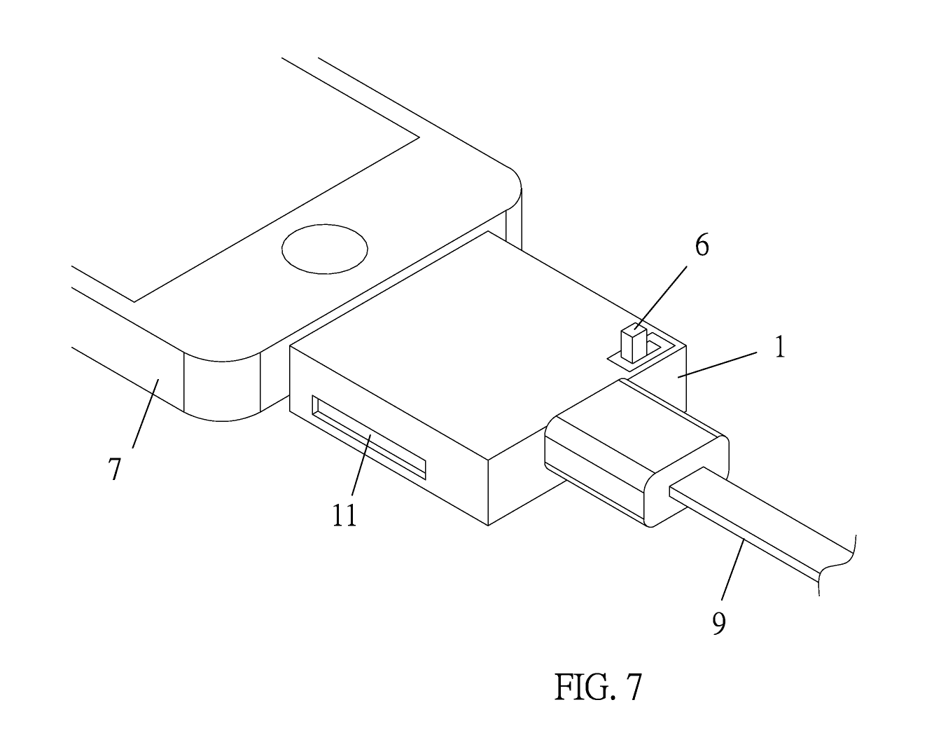

Referring to FIGS. 6 and 7, which are respectively a perspective view illustrating an embodiment of a connection receptacle of the present invention and a schematic view illustrating a use of the connection receptacle, as shown in the drawings, the second connector 5 can be replaced by a connection receptacle 8. The connection receptacle 8 is connectable to a transmission line 9. An opposite end of the transmission line 9 is connectable to an electricity accumulator. The first connector 4 is connectable to the device 7 to allow the electricity accumulator to transmit electrical power to the device 7 to achieve a similar effect.

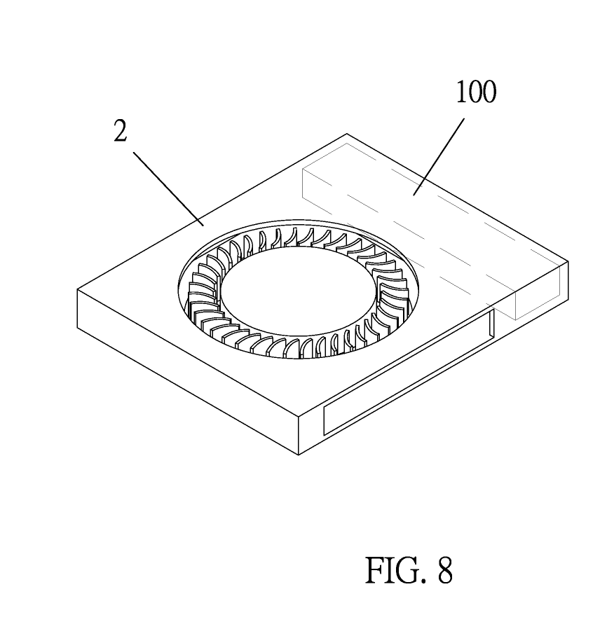

Referring to FIG. 8, which is a perspective view showing an embodiment of the heat dissipation element of the present invention, as shown in the drawings the heat dissipation element 2 comprises an electrical body 100 arranged therein and the electrical body 100 may transmit electrical power to the heat dissipation element 2 to supply the electrical energy necessary for the operation of the heat dissipation element 2 so as to replace the arrangement of electrical connection of the heat dissipation element 2 with the first connector 4 and the second connector 5 discussed in the above for achieving a similar effect. Or, alternatively, an external device may be connected to allow the external device to supply electrical power to the present invention to drive the heat dissipation element 2, thereby achieving an effect of heat dissipation.

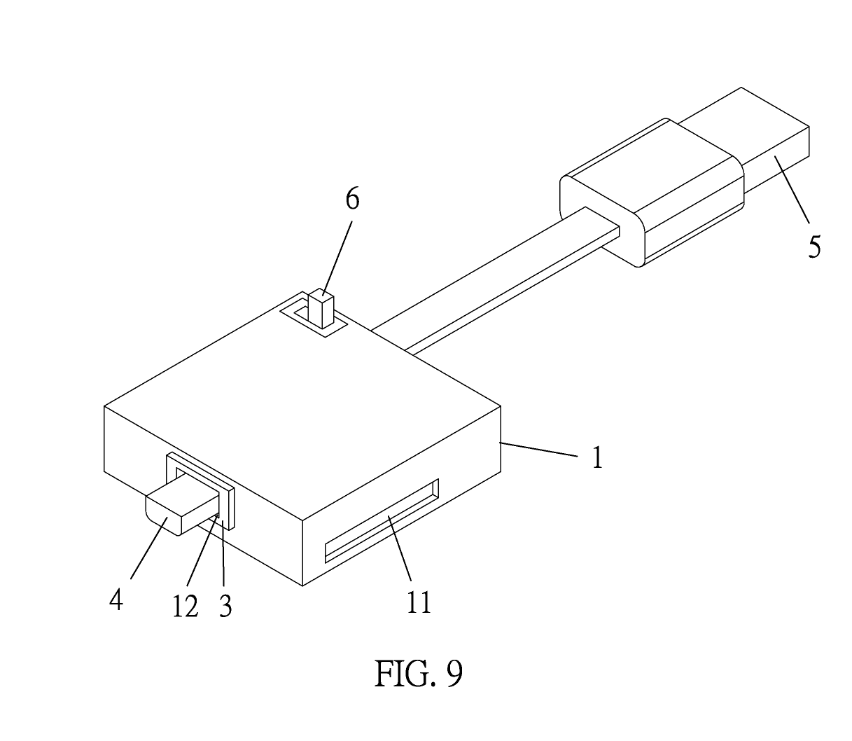

Referring to FIG. 9, which is a perspective view illustrating an embodiment of the present invention, as shown in the drawing, the first connector 4 may comprise a Mini connector, a connector specifically for iPad®, or a Micro connector to suit the needs of different products for easy use by the users.

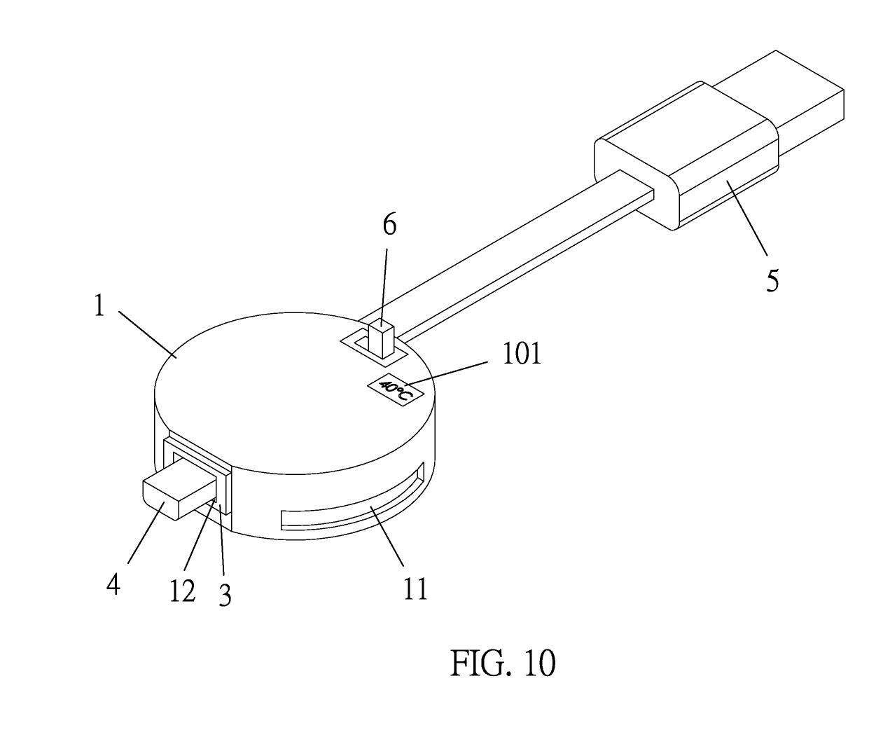

Referring to FIG. 10, which is a perspective view illustrating an embodiment of the present invention, as shown in the drawing, the housing 1 is provided, at any location on a side, an end, or a surface thereof, with a display device 101 for displaying a temperature thereof. The housing 1 may be structured in various shapes, such as a rectangle, a circle, a triangle, and a star.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. A heat dissipation device with charging function, comprising:
at least one heat dissipation element;
at least one first connector, which is arranged at one end of the heat dissipation element; and
at least one second connector, which is arranged at an opposite end of the heat dissipation element, the heat dissipation element, the first connector, and the second connector being in electrical connection with each other.

2. The heat dissipation device with charging function according to claim 1, wherein the heat dissipation element is encased in a housing, the housing comprising at least one air outlet opening formed in a location of one side, one end, or one surface thereof, the housing comprising a surface on which a switch is mounted, the switch being electrically connected to the heat dissipation element, the housing comprising a display device mounted at location of one side, one end, or one surface thereof to display a temperature thereof, the housing having an end to which the first connector is mounted, the housing having an opposite end to which the second connector is mounted, the first connector having a circumference adjacent to which at least one elastic element is arranged, a guiding opening being arranged between the elastic element and the first connector.

3. The heat dissipation device with charging function according to claim 2, wherein the heat dissipation element comprises an electrical body arranged therein to allow the electrical body to supply electrical power necessary for the heat dissipation element, the first connector being alternatively or additionally connectable to an device that supplies electrical power to the heat dissipation element.

4. The heat dissipation device with charging function according to claim 2, wherein the elastic element comprises one of rubber and sponge.

5. The heat dissipation device with charging function according to claim 3, wherein the heat dissipation element comprises a fan and a condensation device.

6. A heat dissipation device with charging function, comprising:
at least one heat dissipation element;
at least one first connector, which is arranged at one end of the heat dissipation element; and
at least one connection receptacle, which is arranged at an opposite end of the heat dissipation element, the heat dissipation element, the first connector, and the connection receptacle being in electrical connection with each other.

7. The heat dissipation device with charging function according to claim 6, wherein the heat dissipation element is encased in a housing, the housing comprising at least one air outlet opening formed in a location of one side, one end, or one surface thereof, the housing comprising a surface on which a switch is mounted, the switch being electrically connected to the heat dissipation element, the housing comprising a display device mounted at location of one side, one end, or one surface thereof to display a temperature thereof, the housing having an end to which the first connection receptacle is formed, the housing having an opposite end in which the connector is mounted, the first connector having a circumference adjacent to which at least one elastic element is arranged, a guiding opening being arranged between the elastic element and the first connector.

8. The heat dissipation device with charging function according to claim 7, wherein the heat dissipation element comprises an electrical body arranged therein to allow the electrical body to supply electrical power necessary for the heat dissipation element, the first connector being alternatively or additionally connectable to an device that supplies electrical power to the heat dissipation element.

9. The heat dissipation device with charging function according to claim 7, wherein the elastic element comprises one of rubber and sponge.

10. The heat dissipation device with charging function according to claim 8, wherein the heat dissipation element comprises a fan and a condensation device.
